(19) United States
(12) Patent Application Publication
(10) Pub. No.: US 2009/0258487 A1
(43) Pub. Date: Oct. 15, 2009

(54) Method for Improving the Reliability of Low-k Dielectric Materials

(76) Inventors: Keng-Chu Lin, Ping-Tung (TW); Chia-Cheng Chou, Keelung City (TW); Chung-Chi Ko, Nantou (TW); Ching-Hua Hsieh, Hsin-Chu (TW); Cheng-Lin Huang, Hsin-Chu (TW); Shwang-Ming Jeng, Hsin-Chu (TW)

Correspondence Address: SLATER & MATSIL, L.L.P., 17950 PRESTON ROAD, SUITE 1000, DALLAS, TX, 75252, US

(21) Appl. No.: 12/102,695

(22) Filed: Apr. 14, 2008

(51) Int. Cl. H01L 21/4763

(52) U.S. Cl. 438/618; 257/E21.495

(57) ABSTRACT

A method for forming an integrated circuit structure includes providing a semiconductor substrate; forming a low-k dielectric layer over the semiconductor substrate; generating hydrogen radicals using a remote plasma method; performing a first hydrogen radical treatment to the low-k dielectric layer using the hydrogen radicals; forming an opening in the low-k dielectric layer; filling the opening with a conductive material; and performing a planarization to remove excess conductive material on the low-k dielectric layer.

### TECHNICAL FIELD

This invention relates generally to integrated circuits, and more particularly to the design and formation methods of interconnect structures of the integrated circuits, and even more particularly to methods for improving the reliability of the interconnect structures.

### BACKGROUND

As the semiconductor industry introduces new generations of integrated circuits (IC's) having higher performance and greater functionality, the density of the elements that form the integrated circuits is increased, and the dimensions, sizes, and spacings between the individual components or elements are reduced. While in the past such reductions were limited only by the ability to define the structures photo-lithographically, device geometries having even smaller dimensions created new limiting factors. For example, for any two adjacent conductive paths, as the distance between the conductors decreases, the resulting capacitance (a function of the dielectric constant (k) of the insulating material divided by the distance between conductive paths) increases. This increased capacitance results in increased capacitive coupling between the conductors, increased power consumption, and an increase in the resistive-capacitive (RC) time constant. Therefore, continual improvement in semiconductor IC's performance and functionality is dependent upon developing materials that form a dielectric film with a lower dielectric constant (k) than that of the most commonly used material, silicon oxide, in order to reduce capacitance.

New materials with low dielectric constants (known in the art as “low-k dielectrics”) are being investigated for use as insulators in semiconductor chip designs. A low dielectric constant material helps to enable further reductions in the integrated circuit feature dimensions. In conventional IC processing, silicon oxide was used as a basis for the dielectric material, resulting in a dielectric constant of about 3.9. Advanced low-k dielectric materials have dielectric constants below about 2.5. The substance with the lowest dielectric constant is air (with a k value equal to 1.0). Therefore, porous dielectrics are very promising candidates, since they have the potential to provide very low dielectric constants.

However, porous films have shortcomings. Poor time-dependent dielectric breakdown (TDDB) performance is one of the major problems. FIG. 1 illustrates a conventional interconnection formation scheme. A first copper line 4 is formed in low-k dielectric layer 2. Etch stop layer 5 is formed on low-k dielectric layer 2. A second copper line 12 is electrically coupled to copper line 4 through via 14. The second copper line 12 and via 14 are formed in low-k dielectric layer 6. Diffusion barrier layer 10 is formed on sidewalls of the trench opening and via opening, in which copper is filled to form the second copper line 12 and via 14.

FIG. 2 schematically illustrates a portion of low-k dielectric layer 6, which is formed of a silicon and carbon containing material. Typically, low-k dielectric layers 2 and 6 may have excess charges, such as electrons (e⁻), trapped therein. These charges affect the electrical performance of metal lines 4 and 12, resulting in the degradation in the TDDB performance. In addition, the formation process often results in dangling bonds. For example, the dangling bonds of silicon are shown in FIG. 2. Conventionally, plasma and/or thermal treatments were used to treat the low-k dielectric layers in order to reduce the charges. However, the conventional treatments may cause carbon depletion, resulting in more dangling bonds. Even worse, the dangling bonds may subsequently be connected with OH terminals, and hence the k values of the low-k dielectric materials adversely increase. In addition, the plasma treatment has the effect of densifying the low-k dielectric materials, which not only causes the increase in the k value of the dielectric materials, but also results in the deep portions of the low-k dielectric materials inadequately treated. New methods are thus needed to solve the above-discussed problems.

### SUMMARY OF THE INVENTION

In accordance with one aspect of the present invention, a method for forming an integrated circuit structure includes providing a semiconductor substrate; forming a low-k dielectric layer over the semiconductor substrate; generating hydrogen radicals using a remote plasma method; performing a first hydrogen radical treatment to the low-k dielectric layer using the hydrogen radicals; forming an opening in the low-k dielectric layer; filling the opening with a conductive material; and performing a planarization to remove excess conductive material on the low-k dielectric layer.

In accordance with another aspect of the present invention, a method for forming an integrated circuit structure includes providing a semiconductor substrate; forming a low-k dielectric layer over the semiconductor substrate; generating hydrogen radicals using a remote plasma method; performing a first hydrogen radical treatment to the low-k dielectric layer using the hydrogen radicals; after the first hydrogen radical treatment, forming an opening in the low-k dielectric layer; filling the opening with a conductive material; and performing a planarization to remove excess conductive material on the low-k dielectric layer.

In accordance with yet another aspect of the present invention, a method for forming an integrated circuit structure includes providing a semiconductor substrate; forming a low-k dielectric layer over the semiconductor substrate; forming an opening in the low-k dielectric layer; filling the opening with a conductive material; performing a planarization to remove excess conductive material on the low-k dielectric layer; generating hydrogen radicals using a remote plasma method; and performing a hydrogen radical treatment to the low-k dielectric layer using the hydrogen radicals after the planarization.

The advantageous feature of the embodiments of the present invention includes improved time independent dielectric breakdown (TDDB), so that the interconnect structures have longer TDDB time.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional interconnect structure including low-k dielectric layers;

FIG. 2 schematically illustrates the dangling bonds and trapped charges in the low k dielectric layers;

FIGS. 3, 4, and 6 through 11 are cross-sectional views of intermediate stages in the manufacturing of an embodiment of the present invention, wherein hydrogen radical treatments are performed to a low-k dielectric layer;

FIG. 5 illustrates a production tool for performing the hydrogen radical treatments;

FIG. 12 shows electrical breakdown resistances of sample low-k dielectric layers as a function of electrical fields;

FIG. 13 shows the time dependent dielectric breakdown performance of sample interconnect structures having different structures, which are treated differently using the hydrogen radical treatments; and

FIG. 14 illustrates breakdown voltages obtained from samples having different structures, which are treated differently using the hydrogen radical treatments.

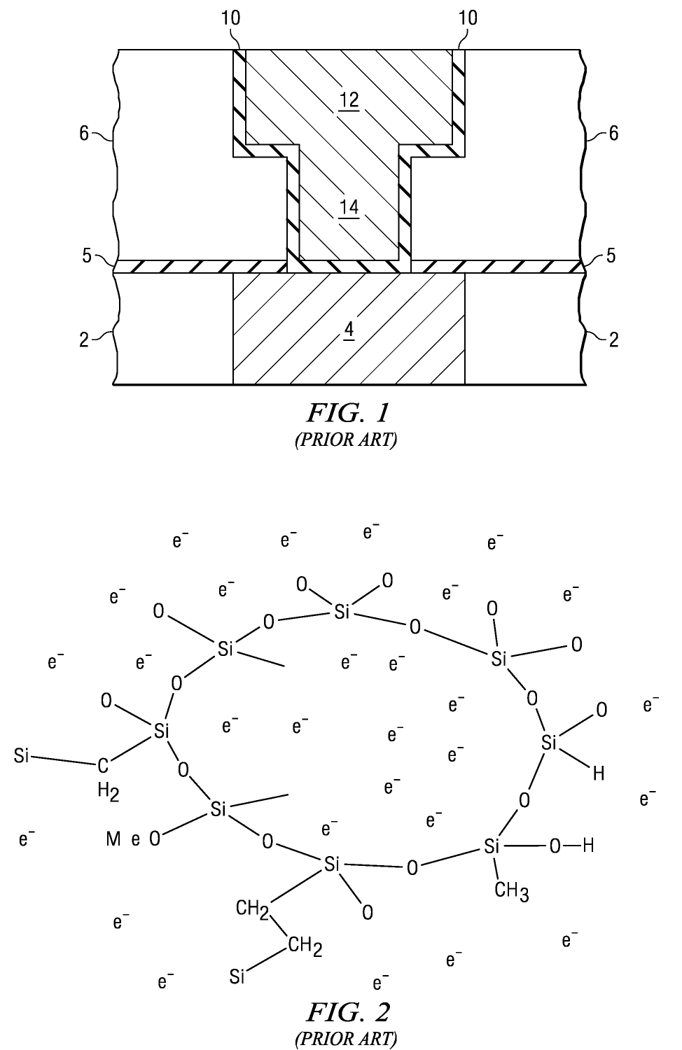

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming a low-k dielectric layer and a corresponding interconnect structure is provided. The intermediate stages for manufacturing the preferred embodiment of the present invention are illustrated. Variations of the preferred embodiments are then discussed. Throughout the various views and illustrative embodiments of the present invention, like reference numbers are used to designate like elements.

FIG. 3 illustrates a starting structure, which includes semiconductor substrate 18, dielectric layer 20, and conductive line 22 formed in dielectric layer 20. Semiconductor substrate 18 may be formed of silicon, germanium, or other commonly used semiconductor materials, and has semiconductor devices such as transistors, capacitors, resistors (not shown), and the like formed thereon. Conductive line 22 is preferably a metal line comprising copper, tungsten, aluminum, silver, gold, alloys thereof, or combinations thereof. Conductive line 22 is typically connected to another underlying feature (not shown), such as a via or a contact plug. Dielectric layer 20 may be an inter-layer dielectric (ILD) layer or an inter-metal dielectric (IMD) layer, and preferably has a low k value, for example, lower than about 3.9, or even lower than about 2.5. For simplicity, semiconductor substrate 18 is not shown in subsequent drawings.

Etch stop layer (ESL) 24 is formed on dielectric layer 20 and conductive line 22. Preferably, ESL 24 may include nitrides, silicon-carbon based materials such as silicon carbonitride, carbon-doped oxides, and combinations thereof. The formation methods may include plasma enhanced chemical vapor deposition (PECVD). However, other commonly used methods such as high-density plasma CVD (HDPCVD), atomic layer CVD (ALCVD), and the like, can also be used.

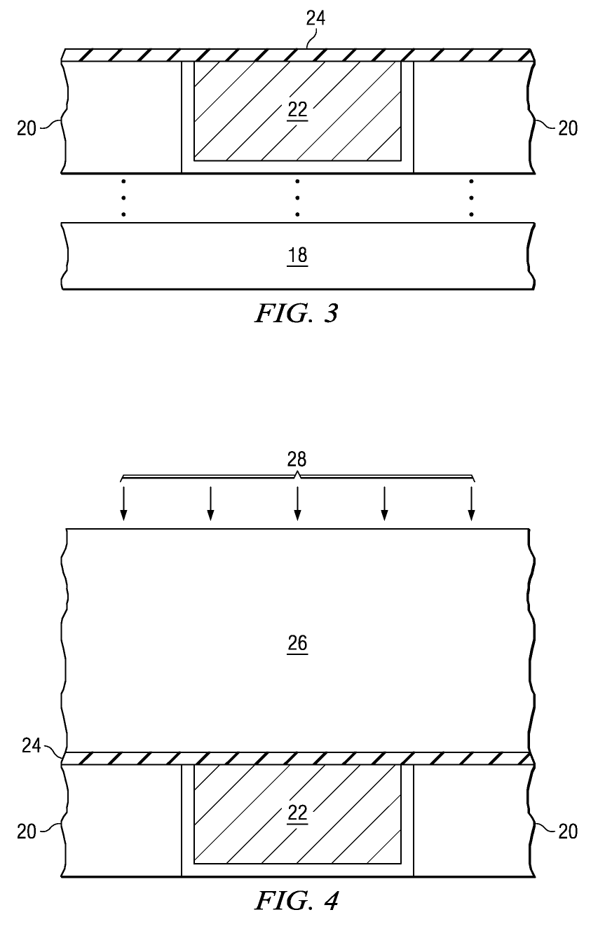

In alternative embodiments, dielectric layer 24 acts as a diffusion barrier layer for preventing undesirable elements, such as copper, from diffusing into the subsequently formed low-k dielectric layer 26 (refer to FIG. 4). In a more preferred embodiment, dielectric layer 24 acts as both an etch stop layer and a diffusion barrier layer.

FIG. 4 illustrates the formation of low-k dielectric layer 26, which provides insulation between conductive line 22 and the overlying conductive lines. Accordingly, low-k dielectric layer 26 is sometimes referred to as an inter-metal dielectric (IMD) layer. Low-k dielectric layer 26 preferably has a dielectric constant (k value) of lower than about 3.5, and more preferably lower than about 2.5, and hence may be an extra low-k (ELK) dielectric layer. The preferred materials include carbon-containing materials, organo-silicate glass, porogen-containing materials, and the like. In an exemplary embodiment, low-k dielectric layer 26 includes silicon and carbon, and possibly oxygen and hydrogen. Low-k dielectric layer 26 may be deposited using a chemical vapor deposition (CVD) method, preferably PECVD, although other commonly used deposition methods, such as low pressure CVD (LPCVD), ALCVD, and spin-on, can also be used.

After the formation, low-k dielectric layer 26 is cured using a curing process. The curing process can be performed using commonly used curing methods, such as ultraviolet (UV) curing, eBeam curing, thermal curing, and the like, and may be performed in a production tool that is also used for PECVD, ALD, LPCVD, or the like. The curing serves the function of driving porogen out of low-k dielectric layer 26, thus lowering its k value, and improving its mechanical property. Pores will then be generated in low-k dielectric layer 26.

A first hydrogen (H) radical treatment is performed on low-k dielectric layer 26, as is symbolized by arrows 28. Preferably, the hydrogen radical treatment is performed using hydrogen radicals, which include atomic or molecular species with unpaired electrons on an otherwise open shell configuration. These unpaired electrons are usually highly reactive, so that the hydrogen radicals are likely to take part in chemical reactions. The hydrogen may be generated using remote plasma. More preferably, the hydrogen radicals used in the treatment include substantially pure hydrogen radicals.

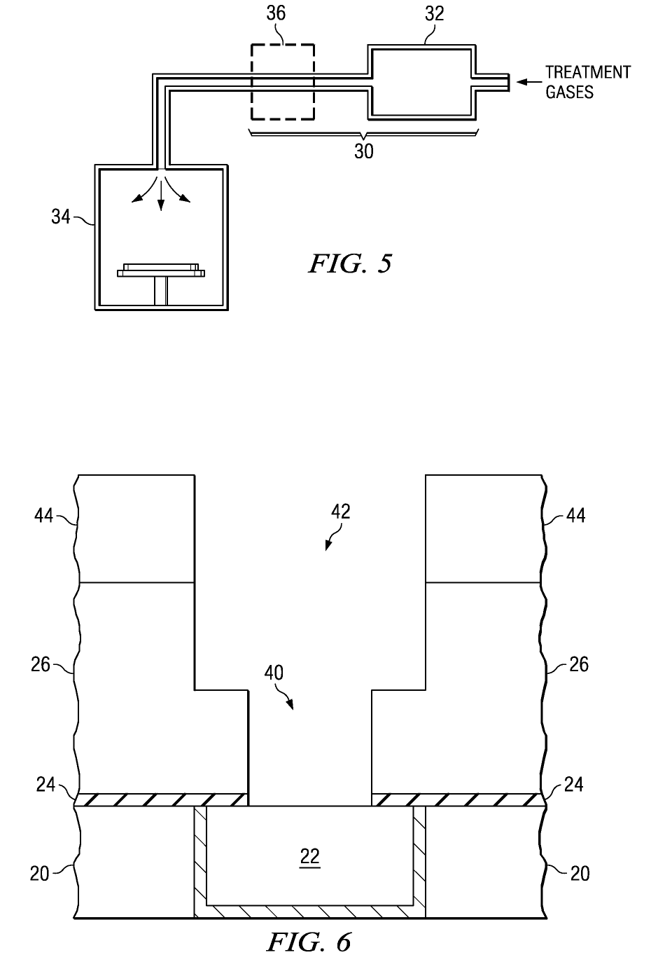

In an embodiment, the hydrogen radicals are generated by remote plasma generating device 30, as is schematically shown in FIG. 5. Remote plasma generating device 30 includes source chamber 32, in which hydrogen radicals are generated. To generate the hydrogen radicals, treatment gases are introduced into source chamber 32, wherein the treatment gases include hydrogen, and may be in the form of H₂, NH₃, N₂H₂, C₂H₂, other gases containing OH terminals, and combinations thereof. In an exemplary embodiment, source chamber 32 has a pressure of between about 10 mtorrs and about 2000 mtorrs, with an exemplary flow rate between about 500 sccm and about 5000 sccm. A power (for example, a RF or DC power) is applied to turn the treatment gases into plasma. An exemplary RF power is between about 100 W and about 4000 W. The generated hydrogen radicals are then introduced into treatment chamber 34, in which the structure shown in FIG. 4 is treated.

It is noted that depending on the type of the treatment gases, the plasma may include various elements such as H₂, H, H⁺, and elements comprising carbon, nitrogen, and the like. Preferably, the hydrogen radicals used for treating low-k dielectric layer 26 include a high percentage of hydrogen radicals. For example, greater than about 70% atomic percent. More preferably, hydrogen radicals including substantially pure hydrogen radicals, for example, greater than about 90% atomic percent. Accordingly, filter 36 may be added between chambers 32 and 34, or built inside chamber 32, to filter the hydrogen radicals, so that treatment chamber 34 has at least a higher percentage, preferably substantially pure, hydrogen radicals. Alternatively, the hydrogen radicals and other elements generated in chamber 32 may be used without being filtered.

The hydrogen radicals are introduced into treatment chamber 34 to treat low-k dielectric layer 26, wherein treatment chamber 34 may be a chamber used for CVD or physical vapor deposition (PVD), or a furnace/baking tool. During the treatment, an exemplary wafer temperature is between about 10° C. and about 400° C. The treatment may last between about 1 minute and about 10 minutes. In order to avoid the bombardment to low-k dielectric layer 26, during the hydrogen radical treatment, no power is applied for generating local plasma purpose. In an embodiment, the hydrogen radical treatment is performed before the curing process. Alternatively, the hydrogen radical treatment may be performed after the curing process. Experiments have revealed both approaches are effective in the improvement of low-k dielectric layer 26.

FIG. 6 illustrates the formation of via opening 40 and trench opening 42 in low-k dielectric layer 26. Photo resist 44 may be applied over low-k dielectric layer 26, and then patterned. Low-k dielectric layer 26 is etched to form trench opening 42. Since there is no etch stop layer for stopping the formation of trench opening 42, etching time is controlled so that the etching of low-k dielectric layer 26 stops at a desired depth. Photo resist 44 is then removed, for example, using an ashing process. An additional photo resist (not shown) may be formed for the formation of via opening 40. In an embodiment, an anisotropic etch cuts through low-k dielectric layer 26 and stops at ESL 24, thereby forming via opening 40. In alternative embodiments, a trench-first approach is taken, in which trench opening 42 is formed prior to the formation of via opening 40. ESL 24 is then etched through via opening 40, exposing underlying conductive line 22.

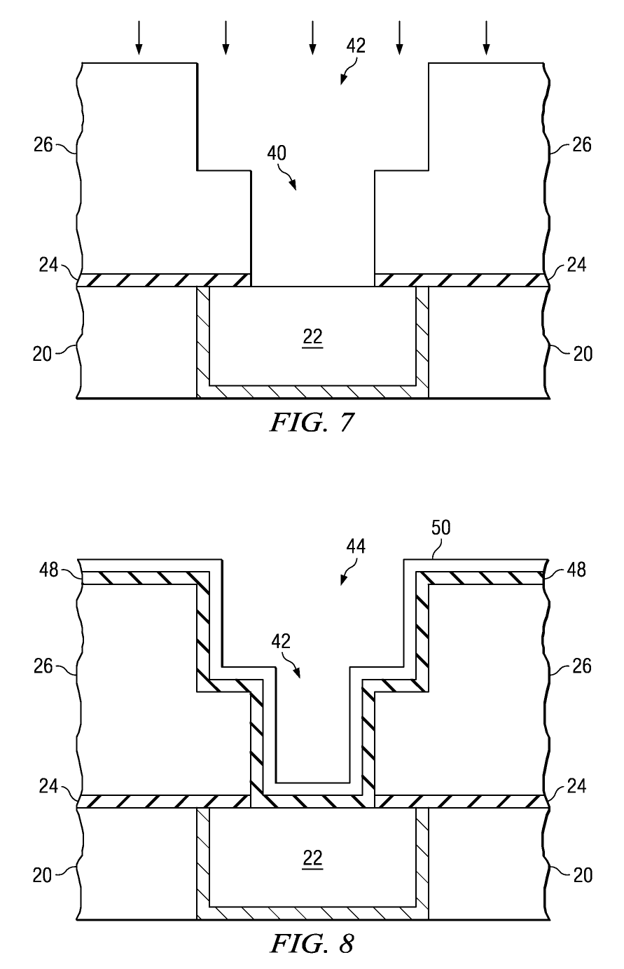

Photo resists are then removed, for example, using an ashing process. The resulting structure is shown in FIG. 7. Since the residues of the photo resists or other materials used in the patterning are often undesirably left, a residue-removal process may be performed. After the patterning of low-k dielectric layer 26 and the residues are fully removed, low-k dielectric layer 26 is exposed. A second hydrogen radical treatment may then be performed, as symbolized by arrows. The second hydrogen radical treatment may be performed using essentially the same materials, process steps, and process conditions as the first hydrogen radical treatment.

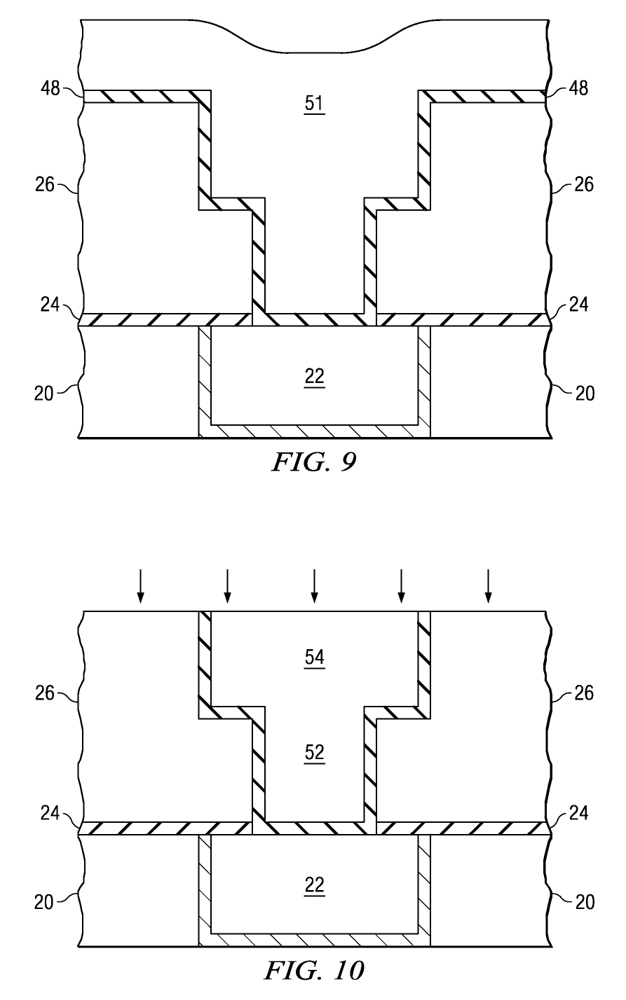

FIG. 8 illustrates the formation of barrier layer 48 and seed layer 50. Barrier layer 48 may be formed of a material comprising titanium, titanium nitride, tantalum, tantalum nitride, and the like. It may be a single or a composite layer. Seed layer 50, preferably comprising copper, is then formed, for example, using electroless plating or PVD. Next, as shown in FIG. 9, via opening 40 and trench opening 42 are filled with conductive material 51, preferably copper or copper alloys. Other metals such as aluminum, tungsten, silver, gold, and alloys thereof, can also be used. A chemical mechanical polish (CMP) is then performed to remove excess conductive material 51 and barrier layer 48 over low-k dielectric layer 26, forming via 52 and metal line 54. The resulting structure is shown in FIG. 10.

After the CMP is performed, low-k dielectric layer 26 is exposed. A third hydrogen radical treatment may then be performed. The third hydrogen radical treatment may be performed using essentially the same materials, process steps, and process conditions as the first and/or the second hydrogen radical treatments. Although in the embodiments discussed in the preceding paragraphs, three hydrogen radical treatments are discussed, the embodiments of the present invention may include only one of the hydrogen radical treatments, or the combination of any two hydrogen radical treatments.

FIG. 11 illustrates the formation of ESL 58 over low-k dielectric layer 26 and metal line 54. ESL 58 may be formed of a dielectric material, for example, silicon nitride, silicon carbide, silicon carbonitride, and the like. ESL 58 also helps improve the reliability of the resulting interconnect structure. The third hydrogen radical treatment discussed in the preceding paragraphs may be a pre-treatment step for forming ESL 58.

In the previously discussed embodiment, the formation of a dual damascene structure is illustrated. The teaching of the present invention can also be applied on the formation of single damascene structures. For example, dielectric layer 20 may be formed of a low-k (or ELK) dielectric material, and treated using hydrogen radical treatments. One skilled in the art will realize the respective process steps by applying the above teaching.

Charges, such as electrons, may be trapped in low-k dielectric layer 26. Through the hydrogen radical treatments, the trapped electrons are neutralized by the positively charged hydrogen ions, resulting in the improvement in the time dependence dielectric breakdown (TDDB) performance. Further, in the formation of low-k dielectric layer 26, dangling bonds may be formed. In the case low-k dielectric layer 26 comprises carbon, silicon, oxygen, and hydrogen, the subsequent processes, such as the ashing steps for patterning low-k dielectric layer 26, may further cause the lost of CH₃ terminals, further increasing the number of dangling bonds (such as Si— bonds). The hydrogen radicals may be connected to the dangling bonds. Accordingly, the low-k dielectric materials become more stable, and the likelihood that the dangling bonds are connected to undesirable terminals (such as OH), is reduced.

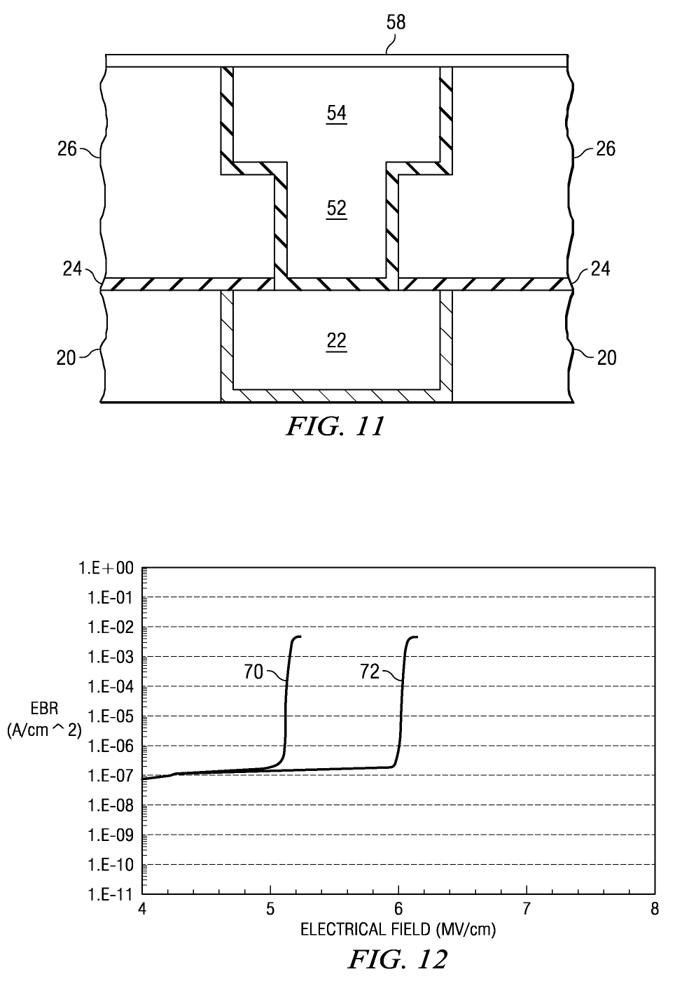

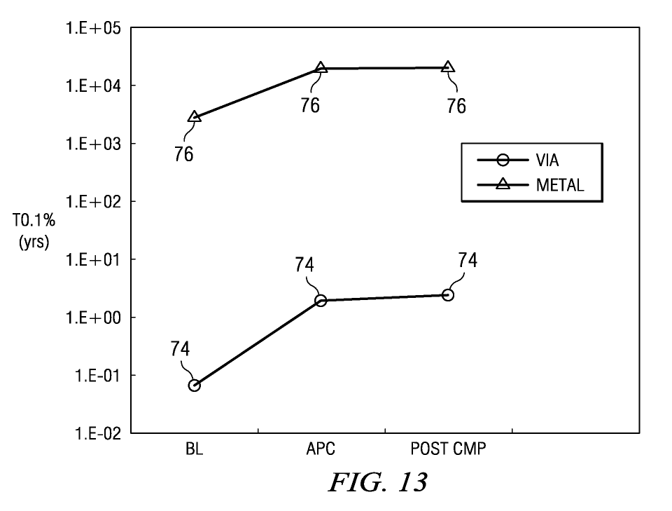

FIG. 12 illustrates the electrical breakdown resistances (EBR) of sample ELK layers, wherein leakage currents in the sample ELK layers are illustrated as the function of electrical fields applied on the sample ELK layers. Line 70 is obtained from a first sample ELK layer formed on a wafer, and no hydrogen radical treatment is performed after the formation of the first sample ELK layer. Line 72 is obtained from a second sample ELK layer formed on a wafer, and a hydrogen radical treatment is performed after the formation of the second ELK layer. It is found that the breakdown of the first ELK layer occurs at an electrical field of about 5 MV/cm, while the breakdown electrical field of the second ELK layer is improved to about 6 MV/cm.

FIG. 13 illustrates a TDDB data of sample metal lines and vias, wherein the Y-axis shows the time at which 0.1 percent of the samples fail. The X-axis shows several types of samples, wherein base line samples (BL) are not treated by hydrogen radical treatments. “APC” indicates the corresponding samples only went through the second hydrogen radical treatment (after the formation of via and trench openings). “Post CMP” indicates the corresponding samples only went through the third hydrogen radical treatment (after the CMP). The results shows that, compared to baseline samples (BL), either the second or the third hydrogen radical treatment alone may improve the TDDB time by greater than about one order for vias (the bottom samples marked as 74). For metal lines (the top samples marked as 76), the improvement in the TDDB time caused by the second or the third hydrogen radical treatment is improved by close to one order.

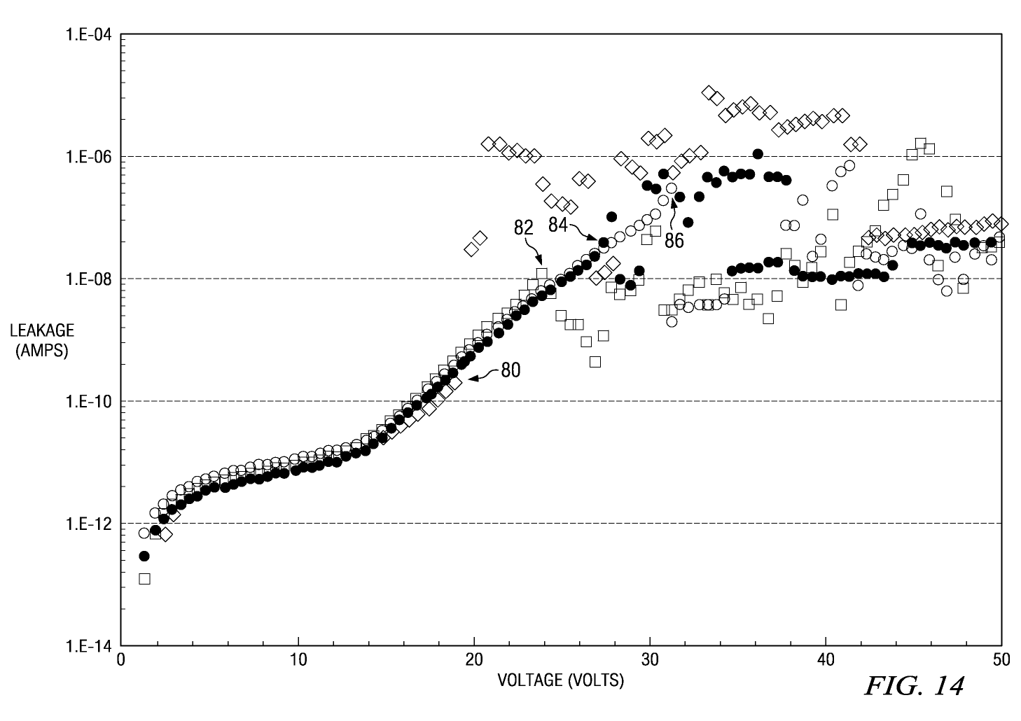

An advantageous feature of the embodiments of the present invention is that the improvement in the reliability and quality of low-k dielectric materials is accumulative to the improvement caused by other methods, such as forming ESL, forming barrier layer, and the like. FIG. 14 illustrates leakage currents of sample interconnect structures (referred to as samples hereinafter) as the function of voltages. The experiment results revealed that the baseline samples (with no hydrogen radical treatment performed, and comprising first ESLs) have a breakdown voltage of about 18 volts (point 80). If the samples include second ESLs but were not treated by hydrogen radical treatments, the breakdown voltage increases to about 24 volts (point 82). In this case, the second ESLs have better quality than the first ESLs. If the second hydrogen radical treatment is performed on the samples with the second ESLs, the breakdown voltage further increases to about 28 volts (point 84). When both the second and the third hydrogen radical treatments are performed on the samples with the second ESLs, the breakdown voltage further increases to about 31 volts (point 86). This proves that not only the hydrogen radical treatments may be combined with ESLs and other conventional methods to further improve the reliability and quality of the low-k dielectric materials, more than one hydrogen radical treatment at different manufacturing stages may be combined to achieve better results than only one hydrogen radical treatment (and a smaller number of hydrogen radical treatments).

Experiments have also revealed the hydrogen radical treatments result in substantially no increase in the k values of the low-k dielectric materials. In an experiment, after a low-k dielectric material is deposited and cured, the k value is about 2.55. After a hydrogen radical treatment, the k value is only about 2.57, which is within the range of measurement errors. As a comparison, an etching step may cause the k value of the low-k dielectric material to increase by about 0.2, while a plasma treatment may cause the k value to increase by about 0.1.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming an integrated circuit structure, the method comprising:
providing a semiconductor substrate;
forming a low-k dielectric layer over the semiconductor substrate;
generating hydrogen radicals using a remote plasma method;
performing a first hydrogen radical treatment to the low-k dielectric layer using the hydrogen radicals;
forming an opening in the low-k dielectric layer;
filling the opening with a conductive material; and
performing a planarization to remove excess conductive material on the low-k dielectric layer.

2. The method of claim 1 further comprising, after the step of forming the low-k dielectric layer, performing a curing to the low-k dielectric layer, wherein the first hydrogen radical treatment is performed before the step of performing the curing.

3. The method of claim 1 further comprising, after the step of forming the low-k dielectric layer, performing a curing to the low-k dielectric layer, wherein the first hydrogen radical treatment is performed after the step of performing the curing.

4. The method of claim 1, wherein the first hydrogen radical treatment is performed after the step of forming the opening, and before the step of filling the opening.

5. The method of claim 4 further comprising removing residues left by the step of forming the opening, wherein the first hydrogen radical treatment is performed after the step of removing the residues.

6. The method of claim 1, wherein the first hydrogen radical treatment is performed after the step of performing the planarization.

7. The method of claim 1 further comprising:
after the step of performing the planarization, forming an additional dielectric layer on the low-k dielectric layer; and
performing a second hydrogen radical treatment using the hydrogen radicals, wherein the first and the second hydrogen radical treatments are performed at different manufacturing stages after the low-k dielectric layer is formed, and before the low-k dielectric layer is covered by the additional dielectric layer.

8. The method of claim 1, wherein an hydrogen plasma is generated by the remote plasma method, and wherein the method further comprises filtering the hydrogen plasma to leave substantially pure hydrogen radicals before the hydrogen radicals are used in the first hydrogen radical treatment.

9. The method of claim 1, wherein, during the first hydrogen radical treatment, the low-k dielectric layer is exposed.

10. A method for forming an integrated circuit structure, the method comprising:
providing a semiconductor substrate;
forming a low-k dielectric layer over the semiconductor substrate;
generating hydrogen radicals using a remote plasma method;
performing a first hydrogen radical treatment to the low-k dielectric layer using the hydrogen radicals;
after the first hydrogen radical treatment, forming an opening in the low-k dielectric layer;
filling the opening with a conductive material; and
performing a planarization to remove excess conductive material on the low-k dielectric layer.

11. The method of claim 10 further comprising, after the step of forming the low-k dielectric layer, performing a curing to the low-k dielectric layer, wherein the first hydrogen radical treatment is performed before the step of performing the curing.

12. The method of claim 10 further comprising, after the step of forming the low-k dielectric layer, performing a curing to the low-k dielectric layer, wherein the first hydrogen radical treatment is performed after the step of performing the curing.

13. The method of claim 10 further comprising a second hydrogen radical treatment after the step of forming the opening and before the step of filling the opening.

14. The method of claim 12 further comprising a second hydrogen radical treatment, wherein the second hydrogen radical treatment is performed after the step of performing the planarization.

15. The method of claim 10 further comprising, after the step of performing the planarization, forming an etch stop layer on the low-k dielectric layer.

16. The method of claim 10, wherein an hydrogen plasma is generated by the remote plasma method, and wherein the method further comprises filtering the hydrogen plasma to leave substantially pure hydrogen radicals before the hydrogen radicals are used in the first hydrogen radical treatment.

17. A method for forming an integrated circuit structure, the method comprising:
providing a semiconductor substrate;
forming a low-k dielectric layer over the semiconductor substrate;
forming an opening in the low-k dielectric layer;
filling the opening with a conductive material;
performing a planarization to remove excess conductive material on the low-k dielectric layer;
generating hydrogen radicals using a remote plasma method; and
after the step of performing the planarization, performing a hydrogen radical treatment to the low-k dielectric layer using the hydrogen radicals.

18. The method of claim 17, wherein the hydrogen radicals are substantially pure.

19. The method of claim 17 further comprising additional hydrogen radical treatments before the hydrogen radical treatment.

20. The method of claim 19, wherein, during the additional hydrogen radical treatments and the hydrogen radical treatment, the low-k dielectric layer is exposed.
